(19) United States
(12) Patent Application Publication
(10) Pub. No.: US 2012/0308762 A1
(43) Pub. Date: Dec. 6, 2012

(54) Method for the Application of a Conformal Nanocoating by Means of a Low Pressure Plasma Process

(75) Inventors: Filip Legein, Oudenaarde (BE); Anthony Vanlandeghem, Oudenaarde (BE); Peter Martens, Oudenaarde (BE)

(73) Assignee: EUROPLASMA NV, Oudenaarde (BE)

(21) Appl. No.: 13/574,626

(22) PCT Filed: Jan. 21, 2011
(86) PCT No.: PCT/EP2011/000242

§ 371 Date: Jul. 26, 2012

(30) Foreign Application Priority Data
Jan. 22, 2010 (BE) 2010/0035

(51) Int. Cl. C23C 16/50; B32B 3/02; C23C 16/30

(52) U.S. Cl. 428/76; 427/488; 427/490

(57) ABSTRACT

The invention relates to a conformal nanocoating applied by a low pressure plasma process. The invention also relates to a method for making such a conformal nanocoating on a three-dimensional nanostructure, in particular a three-dimensional structure containing electrically conductive and non-conductive elements.

The invention relates to a low pressure plasma process for applying a nanocoating conformally on a three-dimensional structure. The invention also relates to applications of such a conformal coating on three-dimensional nanostructures made of different materials, in particular a three-dimensional structure containing electrically conductive and non-conductive elements.

The majority of electronic devices are essentially three-dimensional structures of electrically conductive and electrically insulating materials. Such electronic devices include not only equipment but also assemblies, printed circuit boards (PCBs), both bare and assembled, and individual components such as integrated circuits and transistors. The electrically conductive parts of such structures usually consist of metals such as copper, aluminium, silver or gold, or conductive polymers, or semiconductor material. The electrically non-conductive parts or insulators of these structures usually consist of polymers such as polyimide, polytetrafluoroethylene, silicone, or polyamide, with or without glass-fibre reinforcement, or paper based materials. The insulators in the structure or assembly may also include ceramic materials such as glass. Throughout the lifetime of electronic devices they are subject to various forms of contamination. The conductivity of some of the materials may be reduced by atmospheric corrosion, and pollution can cause conductive paths to become established between adjacent tracks or conductors, with dendrites being an example of this mechanism.

Electronic devices are being used increasingly in hostile and polluted environments and there is a growing use of conformal coatings to protect against contamination. Such conformal coatings are normally non-conductive.

Traditionally conformal coatings have been applied to assembled circuit boards and assembled units but they can also be used on bare circuit boards to prevent the copper pads oxidising prior to soldering and to afford a level of protection from contamination after the assembly process.

The minimum requirements for a conformal coating are that it should provide an effective barrier between the device and the environment and that it should be electrically insulating. The conformal coating should prevent physical contamination, which may, for example, result in conductive growths across the non-conductive parts of the structure or installation, which in time could cause short circuits. Examples of such contamination are dendrites that grow across surfaces under certain conditions and ‘tin whiskers’ that can grow through the air between component leads. The coating must also ensure that the metal does not oxidize in air or corrode in other environmental gases. The coating should prevent such problems arising during the lifetime of the electronic devices. As the environment becomes more aggressive, the greater the demands on the conformal coating will be. The coating will have to withstand high humidity, high temperature and high pollution including dust, salts, acids, solvents, etc.

Traditional conformal coatings are polymers based on silicone (eg JP60047024), epoxy (eg EP0187595), acrylic (eg EP0492828) or urethane (eg CA1144293) and are typically a few tens to a few hundreds of μm thick. They are normally applied by spraying or dipping the devices. Before the coating is applied, it is crucial that the devices are first dried and thoroughly cleaned. After application of the coating there is normally another drying process. It is therefore a production process with several different steps that require a lot of energy and chemicals and therefore is also very damaging to the environment. It is not easy and may even be impossible for traditional coatings to be applied on complex three-dimensional structures, especially as the scale of these structures become increasingly smaller. Many of the conventional coatings are brittle, making them unsuitable for flexible structures. A further problem with many traditional coatings occurs when devices are subjected to repeated thermal cycling when the coating can become detached from the device due to limited adhesion and differences in the expansion characteristics. With many of the conventional coatings it is not possible to solder through them, making it necessary to remove the coating before repairs or upgrades can be carried out.

Parylene coatings have been developed to offer a partial solution to the limitations (eg U.S. Pat. No. 6,389,690). These coatings are applied under vacuum and are therefore well suited to applying to complex three-dimensional structures. The production process is complex because solid precursors are used that have to be sublimated to start with and then a high temperature pyrolysis must be carried out before a useful monomer in the gas phase is formed. Parylene coatings are thinner than traditional conformal coatings, typically less than 1 to tens of micrometers. Different pretreatments remain necessary for proper adhesion of the coating to all the components of a three-dimensional structure including assemblies or sub assemblies, and to ensure that this adhesion is maintained during the lifetime of the product. Like most traditional conformal coatings, parylene coatings must be removed before repairs are carried out. It is not easy to remove such parylene coatings.

The present invention uses plasma polymerization which is a process where a thin polymeric film is deposited on any surface that comes in contact with the plasma of an organic monomer, which has been created in the chamber. Depending on the deposition conditions, also called the plasma parameters, such as power, pressure, temperature, flow, etc, the properties of the film may be adapted to the requirements of the applications of the devices.

In the present invention a nano conformal coating is applied by a low pressure plasma process. The typical layer thickness is between 5 and 500 nm and preferably between 25 and 250 nm, thus fundamentally thinner than any of the existing conformal coating techniques. This coating is therefore very suitable for very complex and small structures providing a uniform coating even in the smallest corners.

The plasma polymerisation process takes place in a vacuum plasma chamber where the parameters controlling the process include power, pressure, temperature, type of monomer, flow, frequency of the plasma generator and process time. The frequency of the generator for the plasma can be in the kHz, MHz and GHz range and it can be pulsed or continuous. The number and placement of the electrodes can also be varied.

The pressure at which the plasma polymerization process is performed is typically between 10 and 1000 mTorr. The process is performed until the desired coating thickness is achieved.

The power used is highly dependent on the monomer used but can typically vary between 5 and 5000 W and can be applied continuously or pulsed. In the pulsed power mode, the pulse repetition frequency is typically between 1 Hz and 100 kHz, with a mark space ratio typically between 0.05 and 50%.

The way that power is applied is heavily dependent on the monomers used. If the molecule is larger and/or less stable, it will easily be decomposed by high power but this results in poor coatings. In such cases, a good quality coating can be best achieved with lower power operation and/or by applying pulsed power with a frequency of 10 to 100 kHz and a mark space ratio of between 0.05% and 1%.

Polymerisable particles from a plasma forming gas are deposited on a surface to form a coating. The monomers used for the starting material are introduced in gaseous form into the plasma, which has been initiated by a glow discharge. The excited electrons created in the glow discharge ionise the monomer molecules. The monomer molecules break apart creating free electrons, ions, excited molecules and radicals. The radicals adsorb, condense and polymerise on the substrate. The electrons and ions crosslink, or create a chemical bond, with the material already deposited on the surface of the substrate.

The creation of free radicals is preferably achieved by using a monomer gas used in a plasma polymerisation process.

The precursors used in the present invention are preferably gaseous and can therefore easily be introduced into the plasma chamber. Alternatively, liquid or solid precursors may be used at atmospheric or reduced pressure and are evaporated by simple heating at temperatures typically does not exceed 200° C. This, in itself represents a significant simplification compared to the parylene coating process.

A range of different precursors can be used for the conformal nanocoating on electronic devices as described.

These precursors should preferably contain halogens and/or phosphorus and/or nitrogen and/or silicone, such as
monomers obtained from one or more of the precursors CF₄, C₂F₆, C₃F₆, C₃F₈, C₄F₈, C₃F₆ C₅F₁₂, C₆F₁₄ and/or other saturated or unsaturated hydrofluorocarbon (C_{X}F_{y})
monomers obtained from acrylates (eg, C₁₃H₁₇O₇F₂), methacrylates (eg, C₁₄H₉F₁₇O₂), or mixtures thereof,
monomers obtained from one or more precursors of trimethyl phosphate, triethyl phosphate, tripropylfosfaat or other derivatives of phosphoric acid,
monomers obtained from one or more of the precursors ethylamine, triethylamine, allylaminee or acrylonitrile, or
monomers obtained from siloxanes, silanes, or mixtures thereof.

The plasma polymerisation process is in practice preferably preceded by one or more plasma processes using the same electrode arrangement and possibly within the same process parameters.

In order to get good adhesion between the conformal coating and all component parts and materials within the structure or assembly, and to retain that adhesion during the entire life of the finished product, it is imperative that all the constituent parts and materials of the structure or assembly are cleaned and/or etched as required. Cleaning means that organic contamination on the surface is removed. Etching means that the material itself is removed and/or roughened. Etching may be required to promote good adhesion on certain materials.

Low pressure plasma processes are particularly suitable for this because the reaction gases are able to permeate throughout the entire three-dimensional structure, unlike liquid based conformal coatings that are limited by surface tension. The process is also dry and provides a safer environment for the operators. Compared to traditional methods of conformal coating, low pressure plasma processes are more beneficial to the environment in general.

Depending on the gas or gas mixture selected, cleaning and/or etching can be carried out on all constituent materials, including conductors, semiconductors and insulators. Typical gases used for plasma cleaning or etching are O₂, N₂, H₂, CF₄, Ar, He, or mixtures thereof.

A major cost saving can be achieved compared to current conformal coating methods because the cleaning, etching and coating can all take place in the same chamber.

To further improve the bond between the conformal coating and all component parts and materials of the structure or assembly, the constituent parts and materials of the structure can be activated. Activation means that new chemical groups are formed on the surface of the material by the surface tension, increasing the affinity of the surface for conformal coating. Typical gases used for plasma activation include O₂, N₂O, N₂, NH₃, H₂, CF₄, CH₄, Ar, He, or mixtures of the foregoing. Again significant savings can be achieved compared to traditional conformal coating methods as a result of carrying out the activation and the coating in the same chamber.

Finally, it is essential to remove any trapped gases or water to achieve and maintain good adhesion between the conformal coating and all component parts and materials in a complex three-dimensional structure or assembly. This allows the gases in the plasma process to penetrate to the core of structure. This can be carried out by baking the structure prior to placing it in a plasma chamber as in conventional conformal coating techniques. The invention described here enables this de-gassing, at least partially to be carried out in the same chamber as the precleaning, etching and plasma polymerization.

The vacuum helps to remove moisture from the structure which improves the adhesion and prevents problems encountered in heat cycling during the lifetime of the products. The pressure range for degassing can be from 10 mTorr to 760 Torr with a temperature range from 5 to 200° C., and can be carried out for between 1 and 120 min, but typically for a few minutes. Again, a significant cost savings may be realized compared to existing conformal coating solutions by carrying out the pre-degassing and coating in the same chamber.

By appropriate choice of process parameters and gas mixtures, cleaning, etching and activation may all be carried out for some combinations of materials and components in a single process step.

Experiments have shown that conformal coating can be used for electronic components such as individual transistors or integrated circuits for example. Such individual components may be coated, after being assembled into a larger system component, which again can be coated according to the method of the present invention. It has also found that these coatings are particularly suitable for both bare PCBs and assembled PCBs.

The conformal nanocoating of the present invention is thus particularly advantageous in the coating of complex structures, where complex can include 3D structures and/or combinations of different materials and/or components.

The method of the present invention allows different materials to be combined in a single nanocoating in the same process (time). The method of the invention also allows nanocoatings to be applied to more complex 3D structures.

In a preferred embodiment of the present invention a nanocoating is applied to printed circuit boards that have already had components attached to them to provide a conformal coating of the assembly. In another preferred form complex sub-structures may first be coated with a conformal nano coating, and then interconnected to form a single complex assembly that can have a subsequent nanocoating applied to it to provide an overall conformal coating. The nano coating as described in this invention provides a water-repellent, oil repellent, salt resistant, acid resistant, and flame retardant protection on all surfaces and parts of the structure or assembly.

Experiments showed that the nano coating is also resistant to high temperatures in excess of 200° C.

The nano coating also exhibits elastic properties which make it suitable for flexible structures or applications that need to be shock resistant.

The nanocoating described in this invention also has the important property that it can be soldered through using standard soldering processes.

In another aspect the present invention relates to the use of the method as described above to nanocoat electronic and micro-electronic components, integrated circuits, printed circuit boards (PCBs), both bare and assembled. The present invention also relates to the use of the abovementioned method for applying a nanocoating to all surfaces and parts of the structure, whereby the nanocoating is water-, oil-, salt-, acid- and flame resistant.

The present invention also relates to the use of the abovementioned method for applying a nanocoating which is elastic en soldable.

In yet another aspect the invention relates to a conformal nanocoating applied to a three-dimensional structure of electrically conductive and non-conductive parts and/or components of different materials. The coating has a thickness between 5 and 500 nm, preferably between 25 and 250 nm. The conformal nanocoating is applied by means of the abovementioned method.

In a further aspect the invention relates to a printed circuit board assembly with a conformal nanocoating as described. The conformal nanocoating is applied by a low pressure plasma process.

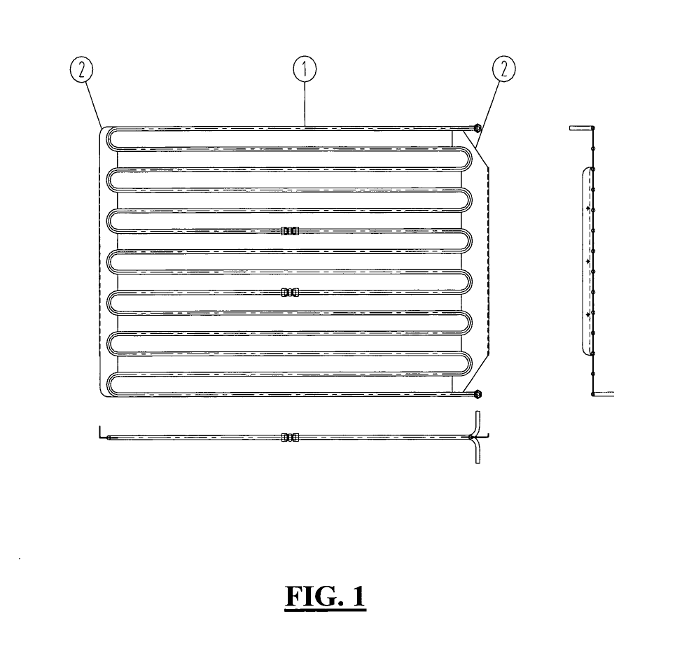

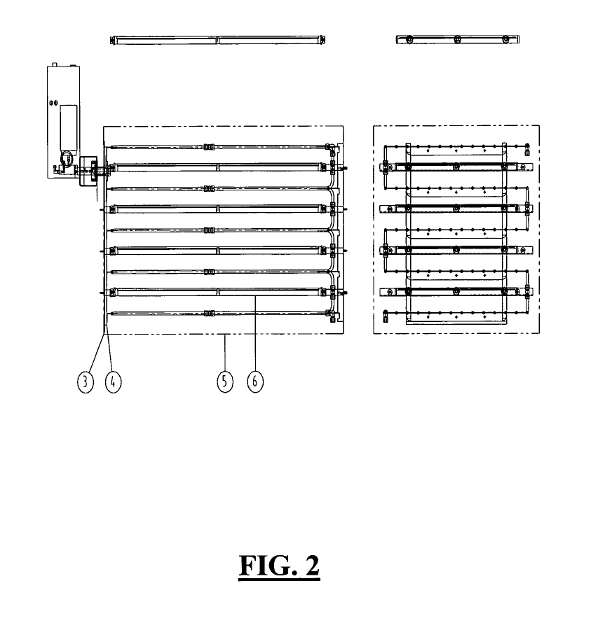

Further advantages of this invention will become apparent by reference to the detailed description of the following exemplary embodiment, to be considered in conjunction with FIGS. 1 and 2, illustrating one or more non limiting aspects of the embodiment.

In the detailed description reference will be made to the enclosed figures which have the following content:

FIG. 1 is a drawing of an individual electrode according to the invention;

FIG. 2 illustrates one embodiment of a multiple electrode arrangement that can be fitted into a vacuum chamber according to the invention.

### EXAMPLE 1

### Electrode Placement in the Reaction Chamber

The arrangement is preferably as shown in FIGS. 1 and 2. The electrode arrangement for generating a low pressure plasma comprises a set of floating electrodes (1) that are hollow, curved and circular in shape, and the vacuum chamber (5) functions as a mass. The electrodes (1) is fed with a liquid, which can be cooled or heated to enable the plasma processes to be performed overin a temperature range of 5 to 200° C., and preferably at a controlled temperature between 20 and 90° C.

A typical electrode (1) in this arrangement has a diameter of between 5 and 50 mm, a wall thickness of 0.25 to 2.5 mm, bending toward the end with a turning circle of 180°, and the distance between the tube before and after the curve is between 1 and 10 times the pipe diameter, preferably 5 times.

Power is applied to the electrode (1) via connecting plates (2) mounted on a clutch plate (4). A thin insulating layer or shield (3) is applied between the clutch plate (4) and chamber (5). The thickness of this layer, typically a few millimetres, is such that in between no plasma is possible.

The three-dimensional structure or installation to which the nanocoating is to be applied, is positioned between the electrodes, by using a perforated metal container or tray (6) that can be pushed between the electrodes for example. It is preferable that a minimum distance of a few mm is maintained between the electrode and the substrate. The floating electrodes in the apparatus described above enables a uniform three-dimensional coating to be applied in a single process step. It is not necessary for the top and bottom of a structure to be coated in two different steps.

The electrodes generate a high frequency electric field at frequencies between 20 kHz to 2.45 GHz, typically 40 kHz or 13.56 MHz, with 13.56 MHz being preferred.

Such an electrode arrangement was fitted into a CD1000 plasma system.

### EXAMPLE 2

### Low Pressure Plasma Polymerization of an Implanted Circuit Board For Phone C3F6

An assembled circuit board for a mobile phone was placed in a CD1000 plasma chamber, as described in Example 1, for over two minutes and degassed at a pressure between 100 and 1000 mTorr. Then the board was cleaned and etched using Ar, and plasma polymerization was carried out for 10 min using a C3F6 monomer at 50 mTorr and at room temperature. The fluoropolymer conformal coating applied by this process was measured to be approximately 80 nm thick.

This circuit board was then exposed to several aging processes involving prolonged exposure to humidity, high temperatures and salt fumes. Visually it could be seen that the circuit board with the conformal nano coating showed significantly less corrosion than an untreated circuit board. When carrying out electrical testing, it was also found that the circuit board assembly with the nanoconformal coating showed virtually no electrical failures, which was significantly less than the uncoated circuit board assemblies.

1-44. (canceled)

45. Method for depositing a conformal nanocoating on all surfaces and all parts of a three-dimensional structure or assembly composed of electrically conductive and electrically non-conductive elements, characterized in that said coating is deposited by a low pressure plasma polymerisation process preceded by a degassing step of the structure or assembly.

46. Method according to claim 45, whereby the degassing and the plasma polymerisation process are processed in the same plasma chamber.

47. Method according to claim 45, whereby the coating has a thickness between 25 and 250 nm, preferably of approximately 80 nm.

48. Method according to claim 45, whereby the plasma process is performed at pressures between 10 and 1000 mTorr, preferably at 50 mTorr.

49. Method according to claim 45, whereby the plasma process is performed at a temperature between 20 to 90° C.

50. Method according to claim 45, whereby the plasma process is performed at a frequency of 20 kHz to 2.45 GHz, preferably 40 kHz, more preferably 13.56 MHz.

51. Method according claim 45, whereby the RF power is continuously maintained during the plasma polymerisation process.

52. Method according to claim 45, whereby the RF power is pulsed during the plasma polymerisation process, and the frequency of the pulses is typically between 1 Hz and 100 kHz, with a mark to space ratio typically between 0.05 and 50%.

53. Method according to claim 45, whereby gaseous polymerisable monomers are used which are produced from gaseous precursors, by heating liquid precursors or by heating solid precursors or by a combination of the foregoing.

54. Method according to claim 53, whereby said monomers are derived from one or more of the precursors CF₄, C₂F₆, C₃F₆, C₃F₈, C₄F₈, C₅F₁₂, C₆F₁₄ and/or any other saturated or unsaturated hydrofluorocarbon (CₓF_{y}).

55. Method according to claim 53, whereby said monomers are derived from acrylates, methacrylates or mixtures thereof.

56. Method according to claim 53, whereby said monomers are derived from siloxanes, silanes, silazanes or mixtures thereof.

57. Use of the method according to claim 45 for coating electronic components, electronic devices, bare printed circuit boards and assemblies thereof.

58. Use of the method according to claim 45 for depositing a nanocoating to provide a water repellent and/or oil repellent protection to all surfaces and parts of the three-dimensional structure or assembly.

59. Three-dimensional structure or assembly comprising a conformal nanocoating deposited by a method according to claim 45 on all surfaces and parts of the structure or assembly.
